(19) United States
(12) Patent Application Publication
(10) Pub. No.: US 2023/0223264 A1
(43) Pub. Date: Jul. 13, 2023

(54) METHOD FOR MANUFACTURING SEMICONDUCTOR STRUCTURE AND SEMICONDUCTOR STRUCTURE

(71) Applicant: CHANGXIN MEMORY TECHNOLOGIES, INC., Hefei City (CN)

(72) Inventor: LING-YI CHUANG, Hefei (CN)

(21) Appl. No.: 18/152,899

(22) Filed: Jan. 11, 2023

(30) Foreign Application Priority Data
Jan. 13, 2022 (CN) 202210038564.9

(51) Int. Cl. H01L 21/18; H01L 21/306; H01L 21/225; H01L 21/324; H01L 21/683; H01L 21/67; H01L 21/66; H01L 21/768

(52) U.S. Cl. CPC H01L 21/187; H01L 21/30625; H01L 21/2253; H01L 21/3247; H01L 21/6835; H01L 21/67253; H01L 22/12; H01L 21/76877; H01L 21/76802; H01L 2221/68372

(57) ABSTRACT

A method for manufacturing a semiconductor structure and the semiconductor structure are provided. In the method, a first wafer is provided, in which the first wafer has a first side and a second side opposite to each other, and a first conductive structure is provided in the first wafer, and an end of the first conductive structure is located in the first wafer. The first wafer is thinned from the second side along a direction perpendicular to the first side, until a thickness of the remaining first wafer reaches a preset thickness to expose the end of the first conductive structure. The thinning includes performing film peeling at least once. In the film peeling, hydrogen ion implantation is performed on the second side to form a hydrogen ion-containing layer in the first wafer; and the first wafer is heated to cause the hydrogen ion-containing layer to fall off.

### CROSS-REFERENCE TO RELATED APPLICATION

The present application claims benefit of Chinese Application No. 202210038564.9, filed on Jan. 13, 2022, the contents of which are hereby incorporated by reference in its entirety.

### BACKGROUND

The wafer bonding technology refers to tightly bonding two homogeneous or heterogeneous wafers through chemical and physical actions. After the wafers are bonded, the atoms at the interface react under the action of an external force to form covalent bonds, such that the bonding interface reaches a specific bonding strength. At present, there is a problem that the total thickness variation (TTV) of the semiconductor structure formed after bonding is large, which affects the stability of the semiconductor structure formed after bonding.

### SUMMARY

Embodiments of the disclosure relate to the field of semiconductor, in particular to a method for manufacturing a semiconductor structure and the semiconductor structure.

According to some embodiments of the disclosure, one aspect of the embodiments of the disclosure provides a method for manufacturing a semiconductor structure, which includes the following operations. A first wafer is provided, in which the first wafer has a first side and a second side opposite to each other, a first conductive structure is provided in the first wafer, and an end of the first conductive structure is located in the first wafer; and the first wafer is thinned from the second side along a direction perpendicular to the first side, until a thickness of the remaining first wafer reaches a preset thickness to expose the end of the first conductive structure. The thinning includes performing film peeling at least once, and the performing film peeling includes the following operations. Hydrogen ion implantation is performed on the second side to form a hydrogen ion-containing layer in the first wafer; and the first wafer is heated to cause the hydrogen ion-containing layer to fall off.

According to some embodiments, another aspect of the embodiments of the disclosure provide a semiconductor structure, which is formed by the manufacturing method described above.

### BRIEF DESCRIPTION OF THE DRAWINGS

One or more embodiments are exemplarily illustrated by the respective figures in the drawings, and the figures in the drawings are not provided to scale, unless otherwise stated.

FIG. 1 to FIG. 4 are schematic diagrams of semiconductor structures corresponding to each operation of a method for manufacturing a semiconductor structure.

FIG. 5 to FIG. 12 are schematic diagrams of semiconductor structures corresponding to each operation of a method for manufacturing a semiconductor structure provided by embodiments of the disclosure.

FIG. 13 to FIG. 15 are schematic diagrams of semiconductor structures corresponding to each operation of another method for manufacturing a semiconductor structure provided by embodiments of the disclosure.

### DETAILED DESCRIPTION

The technical problem to be solved by the embodiments of the disclosure is to provide a method for manufacturing a semiconductor structure and the semiconductor structure, which is at least beneficial to improving the stability of wafer bonding.

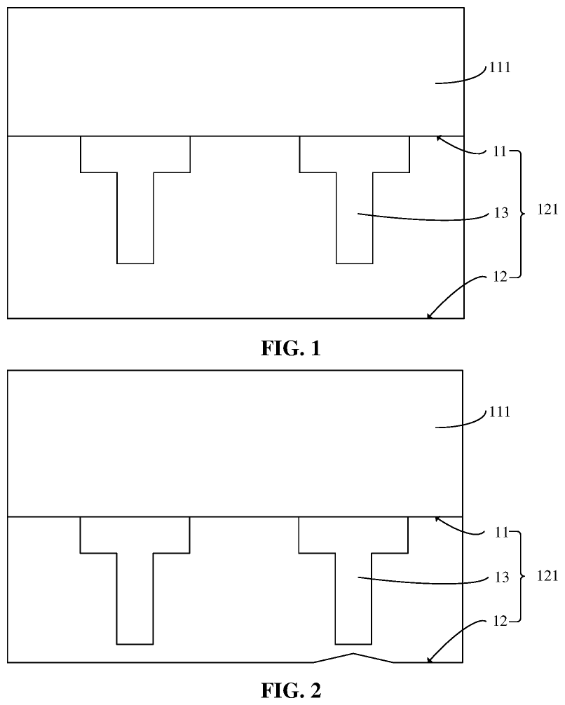

It can be seen from the background that there is a problem that the total thickness variation of the semiconductor structure formed after bonding cannot meet the requirements at present. FIG. 1 to FIG. 4 are schematic diagrams of semiconductor structures corresponding to each operation of a method for manufacturing a semiconductor structure. At present, the method for manufacturing a semiconductor structure includes the following operations.

Referring to FIG. 1, a carrier wafer 111 and a first wafer 121 are provided in a stacked arrangement. The first wafer 121 has a first side 11 and a second side 12 opposite to each other, and a first conductive structure 13 is provided in the first wafer 121, in which the first side 11 exposes the top surface of the first conductive structure 13, and the bottom surface of the first conductive structure 13 is located in the first wafer 121.

The first side 11 may be a front side of the first wafer 121 and the second side 12 may be a back side of the first wafer 121.

Referring to FIG. 2, the second side 12 of the first wafer 121 is polished until the thickness of the remaining first wafer 121 reaches a desired thickness.

Typically, the polishing is performed by a chemical mechanical process, and after the polishing, concave regions may appear in the second side 12 of the first wafer 121.

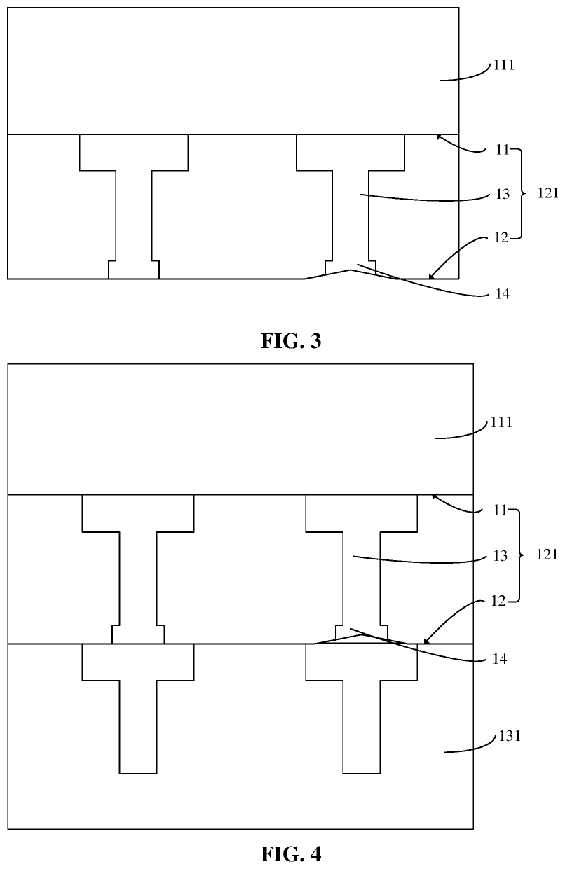

Referring to FIG. 3, a conductive pad 14 is formed in the first wafer 121, in which the conductive pad 14 is in contact with the first conductive structure 13, and the second side 12 exposes the first conductive structure 13.

Referring to FIG. 4, the second wafer 131 is bonded to the first wafer 121 via the second side 12 of the first wafer 121.

The surface of the second side 12 of the first wafer 121 is uneven, which may result in the poor contact between the first conductive structure 13 and the second wafer 131, thereby causing delamination after bonding the first wafer 121 and the second wafer 131, or causing the semiconductor structure formed by bonding to fail to achieve the target function.

The disclosure provides a method for manufacturing a semiconductor structure, in which film peeling is performed on the first wafer by the way of hydrogen ion implantation, so that the flatness of the second side of the first wafer is higher after thinning, thereby providing a process basis for subsequent bonding of semiconductor structures, and further improving the yield of the bonded semiconductor structures.

The embodiments of the present disclosure will be described in detail below with reference to the accompanying drawings. However, those ordinary skilled in the art should understand that in each embodiment of the present disclosure, numerous technical details are proposed for a reader to better understand the present disclosure. But even without these technical details and various variations and modifications based on the following embodiments, the technical solutions claimed in the present disclosure may be implemented.

The method provided by embodiments of the disclosure will be described in more detail below with reference to the drawings.

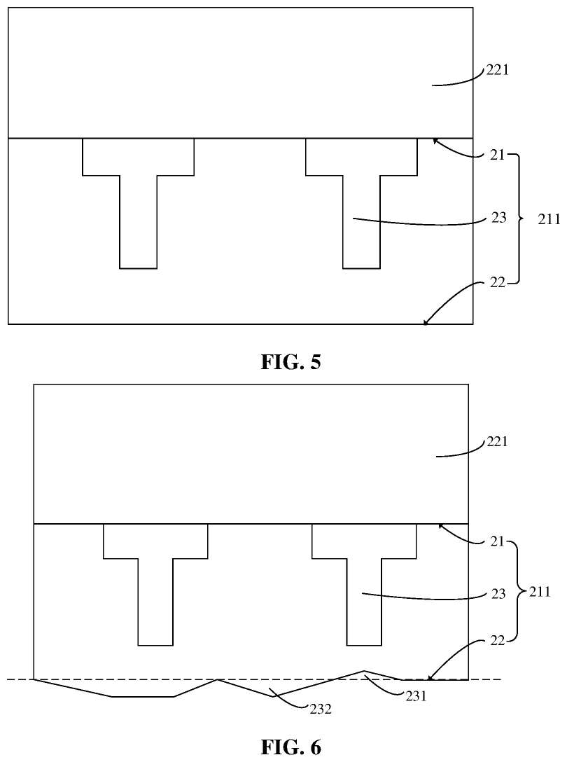

FIG. 5 to FIG. 13 are schematic diagrams of semiconductor structures corresponding to each operation of a method for manufacturing a semiconductor structure provided by embodiments of the disclosure.

Referring to FIG. 5, a first wafer 211 are provided, in which the first wafer 211 has a first side 21 and a second side 22 opposite to each other, and a first conductive structure 23 is provided in the first wafer 211, and an end of the first conductive structure 23 is located in the first wafer 211.

In some embodiments, the first conductive structure 23 may be a through silicon via (TSV). Interconnection in the vertical direction is realized through the TSV, to reduce the area of the semiconductor structure in the horizontal direction and to reduce the interconnection length and signal delay, and so on.

In some embodiments, the first wafer 211 may be a semiconductor wafer such as a silicon wafer, a germanium wafer or the like. Memory cells may be provided in the first wafer 211, and the memory cells may be DRAM memory cells.

The material of the first conductive structure 23 may be a conductive substance such as copper, tungsten, polysilicon or the like.

Subsequently, the first wafer 211 will be thinned to reduce the thickness of the first wafer 211. In some embodiments, before the thinning, the method may further include providing a carrier wafer 221 and bonding the first side 21 of the first wafer 211 with the carrier wafer 221. During the subsequent thinning, the carrier wafer 221 can support the first wafer 211, so as to improve the mechanical strength of the first wafer 211 for protecting the first wafer 211, thereby facilitating the improvement of the flatness of the second side 22 of the first wafer 211 during the thinning.

Specifically, in some embodiments, the carrier wafer 221 may be a wafer of various suitable materials such as a silicon wafer or a glass wafer. It could be understood that, the carrier wafer 221 may also be a wafer made of other semiconductor materials such as germanium, silicon germanium or the like, or made of other metallic materials or nonmetallic materials.

In some embodiments, the materials of the carrier wafer 221 and the first wafer 211 may be different. That is, the carrier wafer 221 and the first wafer 211 are mutually heterogeneous wafers. In the process of bonding the carrier wafer 221 and the first wafer 211, the temperature and the pressure can be controlled to solve the problems such as the thermal mismatch and the lattice mismatch between the carrier wafer 221 and the first wafer 211, thereby improving the bonding quality between the carrier wafer 221 and the first wafer 211.

In other embodiments, the materials of the carrier wafer 221 and the first wafer 211 may be the same. That is, the carrier wafer 221 and the first wafer 211 are mutually homogeneous wafers, for example, both are silicon substrates. In the process of bonding the carrier wafer 221 and the first wafer 211, the carrier wafer 221 and the first side 21 of the first wafer 211 can be directly attached to each other at room temperature, and then be annealed to improve the bonding strength, so that the two wafers can be combined into a whole. In order to improve the bonding strength between wafers, annealing generally needs to be performed at 800° C. to 1000° C.

Referring to FIG. 6 to FIG. 9, the first wafer 211 is thinned from the second side 22 and along a direction perpendicular to the first side 21, until a thickness of the remaining first wafer 211 reaches a preset thickness to expose an end of the first conductive structure 23. The thinning includes performing film peeling at least once. The film peeling includes: performing hydrogen ion implantation on the second side 22 to form a hydrogen ion-containing layer 251 in the first wafer 211; and heating the first wafer 211 to cause the hydrogen ion-containing layer 251 to fall off.

By forming the hydrogen ion-containing layer 251 and peeling off the hydrogen ion-containing layer 251, the flatness of the second side 22 of the first wafer 211 can be higher after the thinning, thereby providing a process basis for the subsequent bonding of the semiconductor structures, further improving the yield of the semiconductor structure formed by bonding.

Referring to FIG. 6, in some embodiments, prior to performing the film peeling, the method further includes polishing the first wafer 211 along a direction from the second side 22 to the first side 21, until the thickness of the remaining first wafer 211 becomes an initial thickness, in which the initial thickness is larger than the preset thickness.

Since the depth of each hydrogen ion implantation is limited, a partial thickness of the first wafer 211 is first removed by polishing, in order to reduce the process duration. In this way, the number of times of performing the film peeling can be reduced and the process duration of performing film peeling can be reduced.

In some embodiments, the polishing may be carried out by chemical mechanical polishing.

Specifically, during polishing the first wafer 211, the surface of the second side 22 of the first wafer 211 after polishing may be uneven, which may lead to the formation of a defective third conductive structure in the downstream process for forming the third conductive structure, thereby affecting the stability of the semiconductor structure formed after bonding.

In some embodiments, after the polishing, the method may further include measuring a flatness of the surface of the second side 22. By measuring the flatness of the surface of the second side 22, some areas with higher surface height of the second side 22 can be thinned accordingly, so as to facilitate the subsequent film peeling.

In some embodiments, the apparatus for measuring the flatness of the surface of the second side 22 includes a laser interferometer. The height difference of the surface of the second side 22 can be measured more accurately by the laser interferometer with higher precision, so that a theoretical basis may be provided for the thickness of the first wafer 211 to be removed by the subsequent thinning, which facilitates the subsequent film peeling.

After the polishing and prior to performing the film peeling, the method further includes the following operation. A concave structure 231 and a convex structure 232 are formed at the second side when polishing. The hydrogen ion implantation is performed on the convex structure 232 formed when polishing, in which the depth of the hydrogen ion implantation is the same as the depth difference between the convex structure 232 and the concave structure 231 formed when polishing.

It could be understood that the first wafer 211 vibrates during polishing, which causes the surface of the polished side to be uneven, that is, some concave structures 231 and convex structures 232 may appear on the second side 22 of the first wafer 211. The concave structure 231 and the convex structure 232 would cause the stability of the semiconductor structure formed subsequently by bonding and the bonding yield to decrease. Therefore, the concave structure 231 and the convex structure 232 need to be processed, in order to make the second side 22 of the first wafer 211 relatively flat, thereby improving the stability of the semiconductor structure formed subsequently by bonding and the bonding yield.

In some embodiments, an ionic reaction between hydrogen ions and ions in the first wafer 211 occurs by hydrogen ion implantation, so that part of the chemical bonds in the first wafer 211 are broken. The flatness of the second side 22 of the first wafer 211 can be improved by removing the part of the reacted first wafer 211.

It could be understood that the depth of hydrogen ion implantation is related to the concave structure 231 and the convex structure 232. That is, the higher the height difference between the concave structure 231 and the convex structure 232, the deeper the depth of hydrogen ion implantation.

It should be noted that the specific shapes of the concave structure 231 and the convex structure 232 are related to the method of polishing, the corresponding tool of the polishing, and the like. The shapes of the concave structure 231 and the convex structure 232 are not limited in the disclosure.

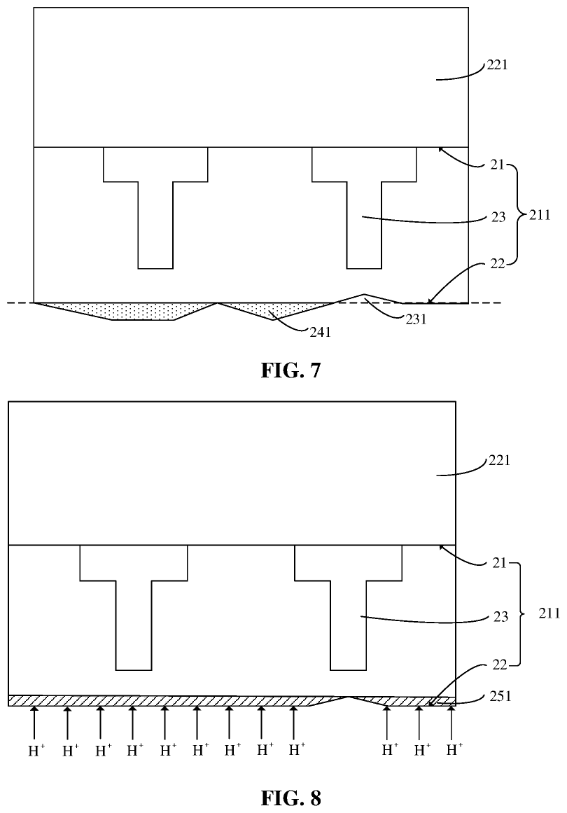

Referring to FIG. 7, prior to the hydrogen ion implantation, the method further includes oxidizing the convex structure 232 on the surface of the second side 22 to form an oxide layer 241 and removing the oxide layer 241.

A partial thickness of the first wafer 211 is removed by forming the oxide layer 241, so as to improve the flatness of the surface of the second side 22.

A local oxidation may be performed according to the flatness of the second side 22 of the first wafer 211. From the second side 22, in the direction perpendicular to the first side 21, the thicker the first wafer 211, the thicker the formed oxide layer 241 may be. Since the thickness of the first wafer 211 removed by each film peeling is limited, the flatness of the second side 22 is improved by removing the oxide layer 241, thereby reducing the number of times of the film peeling and reducing the process duration of manufacturing the semiconductor structure.

In some embodiments, in order to performing the local oxidation of the second side 22, a protective layer is usually formed on the surface of the second side 22 which does not need to be oxidized, that is, on the surface of the second side 22 which is thinner from the first side 21 in the direction perpendicular to the second side 22, and then the surface of the first wafer 211 is oxidized, and the protective layer on the surface of the second side is removed after the oxidizing is completed.

In some embodiments, the oxidizing includes an in-situ steam generation oxidation or a furnace oxidation. The oxide layer 241 formed by the in-situ steam generation oxidation or the furnace oxidation has higher compactness, and the flatness of the second side 22 of the first wafer 211 after removing the oxide layer 241 is higher. In other embodiments, the first wafer 211 may be oxidized by an oxidizing reagent to form the oxide layer 241.

In some embodiments, the material of the first wafer 211 is silicon, and the oxide layer 241 formed correspondingly is silicon oxide. The method of removing the oxide layer 241 may be to etch the oxide layer 241 by using a hydrofluoric acid solution with a molar concentration of 40% to 60%.

Referring to FIG. 8, hydrogen ions are implanted from the second side 22, in which the greater the depth difference between the convex structure 232 (refer to FIG. 6) and the concave structure 231, the deeper the depth of hydrogen ion implantation.

It could be understood that, the greater the depth difference between the convex structure 232 (refer to FIG. 6) and the concave structure 231, that is, from the first side 21 in the direction perpendicular to the second side 22, the thicker the part of the first wafer 211 where the convex structure 232 (refer to FIG. 6) is located, the higher the thickness of the first wafer 211 need to be removed, in order to improve the flatness of the surface of the second side 22 of the first wafer 211.

Specifically, in some embodiments, hydrogen ion implantation may be performed throughout the second side 22 of the first wafer 211.

In the direction perpendicular to the second side 22 from the first side 21, the dose of implanted hydrogen ions can be adjusted according to the thickness of the first wafer 211 to increase the depth of hydrogen ion implantation in the second side 22 of the first wafer 211, and a hydrogen ion-containing layer 251 with a non-uniform thickness on the surface of the second side 22 is formed.

In some embodiments, hydrogen ion implantation may be performed by an ion implanter.

With a constant strong current, a large amount of hydrogen ions are injected from the second side 22 of the first wafer 211 to form a hydrogen ion-containing layer 251.

Specifically, the ion implanter may include an ion beam assembly for providing an ion beam and a base assembly for holding an object to be implanted with ions.

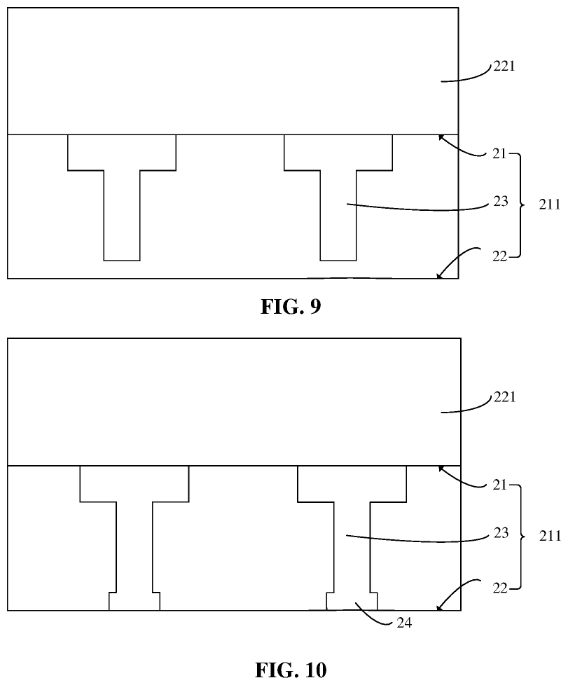

Referring to FIG. 9, the hydrogen ion-containing layer 251 (refer to FIG. 8) is heated such that the hydrogen ion-containing layer 251 (refer to FIG. 8) falls off. In some embodiments, the heating temperature for heating the hydrogen ion-containing layer is 400-600° C.

The temperature of 400° C. to 600° C. causes the surface where the hydrogen ion-containing layer 251 (refer to FIG. 8) is connected to the first wafer 211 to create a continuous cavity, so that the hydrogen ion-containing layer 251 (refer to FIG. 8) automatically falls off from the surface of the first wafer 211.

In some embodiments, the hydrogen ion-containing layer 251 (refer to FIG. 8) having different surface heights at the second side 22 of the first wafer 211 may fall off by heating once. That is, the hydrogen ion-containing layer 251 (refer to FIG. 8) having a non-uniform thickness is formed on the surface of the second side 22 of the first wafer 211 by performing local hydrogen ion implantation multiple times, and then the hydrogen ion-containing layer 251 falls off by heating once.

In other embodiments, local hydrogen ion implantation may be performed according to the flatness of the second side after removing the oxide layer, to form a hydrogen ion-containing layer on a part of the first wafer, and then the hydrogen ion-containing layer is heated to cause the hydrogen ion-containing layer on the part of the wafer to fall off. Next, the flatness of the second side of the remaining first wafer is obtained, and local hydrogen ion implantation is performed again according to the newly obtained flatness, to form a new hydrogen ion-containing layer, then the newly formed hydrogen ion-containing layer is heated to cause it to fall off. Hydrogen ion implantations are repeatedly performed on highest regions of the second side of the first wafer relative to the first side, and then the hydrogen ion-containing layer is heated to fall off, until the total thickness difference of the second side of the remaining first wafer is less than 0.5 μm.

The flatness of the surface of the second side 22 of the first wafer 211 can be improved in such a manner that the hydrogen ion-containing layer 251 (refer to FIG. 8) is heated to fall off. After the hydrogen ion-containing layer 251 (refer to FIG. 8) falls off, the thickness difference of the surface of the second side 22 of the first wafer 211 in a direction from the second side 22 to the first side 21 may be less than or equal to 0.2 μm, so that the yield of semiconductor structure is improved.

In some embodiments, the thinning includes performing film peeling multiple times, in which an implantation depth of the hydrogen ion implantation gradually becomes smaller from a first hydrogen ion implantation to a last hydrogen ion implantation.

Film peeling are performed multiple times, until the thickness of the remaining first wafer 211 reaches a preset thickness. That is, a hydrogen ion-containing layer 251 (refer to FIG. 8) is formed by performing hydrogen ion implantation multiple times and is heated to fall off, such that the first wafer 211 having a high flatness at the second side 22 of the first wafer 211 is formed without polishing.

Referring to FIG. 10, prior to bonding the first wafer 211 and the second wafer, the method further includes forming a groove at the second side 22 of the first wafer 211, in which the groove exposes the first conductive structure 23; and forming a third conductive structure 24 in the groove, in which the third conductive structure is electrically connected with the first conductive structure 23.

In some embodiments, the third conductive structure may also not be formed. The bonding of the second wafer with the first wafer via the third conductive structure 24 may increase the contact area of the conductive structures, and thus reduce the resistance of the contact surface, compared to not forming the third conductive structure.

In some embodiments, the third conductive structure 24 may also be formed by downstream damascene process. In this way, contact resistance can be reduced and connectivity between the first conductive structure 23 and the third conductive structure 24 may be improved.

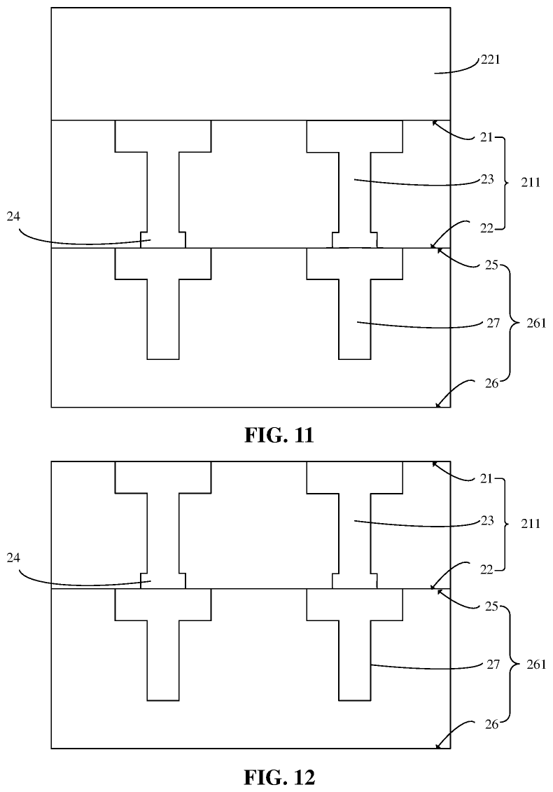

Referring to FIG. 11, a second wafer 261 is also provided, in which the second wafer 261 has a front side 25 and a back side 26 opposite to each other, and the front side 25 of the second wafer 261 exposes the second conductive structure 27. After the thinning, the second side 22 of the first wafer 211 is bonded to the front side 25 of the second wafer 261.

In some embodiments, the second wafer 261 may be a silicon wafer or a germanium wafer, and the wafer material of the second wafer 261 may be the same as that of the first wafer 211.

The second conductive structure 27 may be the same as the first conductive structure 23. The first wafer 211 and the second wafer 261 are bonded to achieve interconnection in the vertical direction, to reduce the area of the semiconductor structure in the horizontal direction.

In other embodiments, prior to bonding the first wafer and the second wafer, the second side of the first wafer and the front side of the second wafer may also be oxidized. Prior to oxidizing, second protective layers are formed on the exposed surfaces of the second conductive structure and the third conductive structure, to prevent the second conductive structure and the third conductive structure from being oxidized. The second protective layers are removed after oxidizing. During bonding the first wafer and the second wafer, the oxide film formed by oxidizing is bonded to the oxide film formed by oxidizing, and the conductive structure is bonded to the conductive structure, such that the first wafer and the second wafer are bonded.

Referring to FIG. 12, after bonding the second side 22 of the first wafer 211 and the front side 25 of the second wafer 261, the method further includes removing the carrier wafer 221 (refer to FIG. 11).

In this embodiment, the carrier wafer 221 (refer to FIG. 11) improves the mechanical strength of the first wafer 211 during polishing, and the carrier wafer 221 (refer to FIG. 11) itself does not have a function. The carrier wafer 221 (refer to FIG. 11) is removed after bonding the first wafer 211 and the second wafer 261.

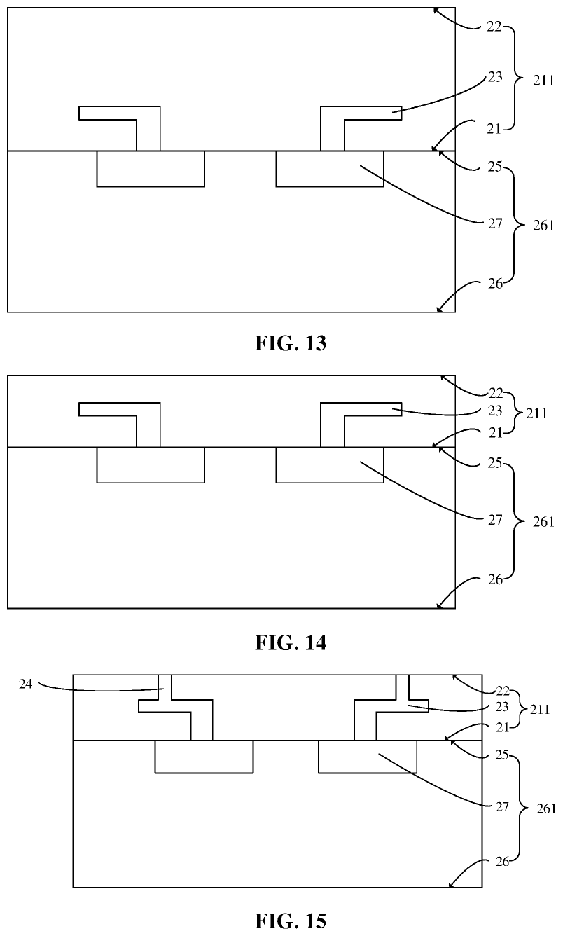

Referring to FIG. 13, in other embodiments, the wafer materials of the first wafer 211 and the second wafer 261 are different. That is, the first wafer 211 and the second wafer 261 are mutually heterogeneous wafers, and the first side 21 of the first wafer 211 and the front side 25 of the second wafer 261 may be directly bonded.

Referring to FIG. 14 and FIG. 15, the second side 22 of the first wafer 211 is thinned by hydrogen ion implantation until the thickness of the remaining first wafer 211 reaches a preset thickness. A groove is formed from the second side 22 in the direction perpendicular to the first side 21, which exposes the first conductive structure 23, and then a conductive material is filled in the groove to form a third conductive structure 24. The signal of the first conductive structure 23 is led out through the third conductive structure 24.

In some embodiments, the thinning of the second side 22 of the first wafer 211 may be performed first by chemical mechanical polishing, and then by performing film peeling to improve the flatness of the second side 22 of the first wafer 211. During chemical mechanical polishing, the second wafer 261 improves the mechanical strength of the first wafer 211.

In the embodiments of the disclosure, the second side 22 of the first wafer 211 is thinned after the first side 21 of the first wafer 211 is bonded with the carrier wafer 221 and a hydrogen ion-containing layer is formed by hydrogen ion implantation and is heated to fall off, to improve the flatness of the second side 22 of the first wafer 211, so that the bonding degree of the bonding interface to be formed subsequently is improved and further the stability of the semiconductor structure is improved.

Referring to FIG. 15, an embodiment of the disclosure also provides a semiconductor structure. The semiconductor structure includes a first wafer 211 and a second wafer 261, in which the first wafer 211 has a first side 21 and a second side 22 opposite to each other, and has a first conductive structure 23 and a third conductive structure 24, and the second wafer 261 has a front side 25 and a back side 26 opposite to each other, and has a second conductive structure 27.

The first conductive structure 23 is electrically connected to the third conductive structure 24. The second side 22 exposes the surface of the third conductive structure 24, and the front side 25 of the second wafer 261 exposes the second conductive structure 27. The first wafer 211 and the second wafer 261 are bonded via the first side 21 and the front side 25, and the second conductive structure 27 is electrically connected to the third conductive structure 24.

The embodiments of the disclosure provide a semiconductor structure with a high flatness of the bonding interface to improve the bonding degree of the bonding interface, so that the stability of the semiconductor structure is improved.

The technical solutions provided by the embodiments of the disclosure at least have the following advantages.

In the technical solutions described above, a first wafer is provided, in which the first wafer has a first side and a second side opposite to each other and a first conductive structure is provided in the first wafer; the first wafer is thinned from the second side thereof along a direction perpendicular to the first side, until the thickness of the first wafer reaches a desired thickness. Herein, the thinning includes performing film peeling at least once. The film peeling includes the following operations. Hydrogen ion implantation is performed on the second side to form a hydrogen ion-containing layer, and heating is performed to make the hydrogen ion-containing layer fall off. In this way, the flatness of the second side of the thinned first wafer is improved, thereby facilitating subsequent processing of the semiconductor structure.

Those of ordinary skill in the art will appreciate that the above-described embodiments are specific embodiments for implementing the present disclosure and that in practical application various changes may be made in form and details thereof without departing from the spirit and scope of the present disclosure. Any person skilled in the art may make their own changes and modifications without departing from the spirit and scope of this disclosure, so the scope of protection of this disclosure shall be subject to the scope defined by the claims.

1. A method for manufacturing a semiconductor structure, comprising:
providing a first wafer having a first side and a second side opposite to each other, a first conductive structure being provided in the first wafer, and an end of the first conductive structure being located in the first wafer; and
thinning the first wafer from the second side along a direction perpendicular to the first side, until a thickness of the remaining first wafer reaches a preset thickness to expose the end of the first conductive structure, wherein the thinning comprises performing film peeling at least once and the film peeling comprises:
performing hydrogen ion implantation on the second side to form a hydrogen ion-containing layer in the first wafer; and
heating the first wafer to cause the hydrogen ion-containing layer to fall off

2. The method according to claim 1, wherein prior to the film peeling, the method further comprises:
polishing the second side of the first wafer from the second side along the direction perpendicular to the first side, until the thickness of the remaining first wafer becomes a first thickness, the first thickness being larger than the preset thickness.

3. The method according to claim 2, wherein prior to the polishing, the method further comprises: providing a carrier wafer; and bonding the first side of the first wafer with the carrier wafer.

4. The method according to claim 3, further comprising: providing a second wafer having a front side and a back side opposite to each other, wherein the front side of the second wafer exposes a second conductive structure; and after the thinning, bonding the second side of the first wafer with the front side of the second wafer.

5. The method according to claim 4, wherein prior to bonding the first wafer with the second wafer, the method further comprises:
forming a groove at the second side of the first wafer, the groove exposing the first conductive structure; and
forming a third conductive structure in the groove, the third conductive structure being electrically connected with the first conductive structure.

6. The method according to claim 5, wherein after bonding the second side of the first wafer with the front side of the second wafer, the method further comprises: removing the carrier wafer.

7. The method according to claim 2, wherein after the polishing, the hydrogen ion implantation is performed throughout the second side of the polished first wafer.

8. The method according to claim 2, wherein after the polishing and prior to the film peeling, the method further comprises:
performing hydrogen ion implantation on a convex structure formed at the second side when polishing, wherein a depth of the hydrogen ion implantation is the same as a depth difference between the convex structure and a concave structure formed at the second side when polishing.

9. The method according to claim 8, wherein prior to the hydrogen ion implantation, the method further comprises: oxidizing the convex structure on a surface of the second side to form an oxide layer; and removing the oxide layer.

10. The method according to claim 9, wherein the oxidizing comprises an in-situ steam generation oxidation or a furnace oxidation.

11. The method according to claim 2, wherein after the polishing, the method further comprises:
measuring a flatness of the second side.

12. The method according to claim 11, wherein an apparatus for measuring the flatness of the second side comprises a laser interferometer.

13. The method according to claim 1, wherein a heating temperature for the heating the first wafer is 400-600° C.

14. The method according to claim 1, wherein the thinning comprises performing the film peeling multiple times, wherein an implantation depth of the hydrogen ion implantation gradually becomes smaller from a first hydrogen ion implantation to a last hydrogen ion implantation.

15. A semiconductor structure formed by the method for manufacturing a semiconductor structure according to claim 1.
